(19) United States
(12) Patent Application Publication
(10) Pub. No.: US 2024/0068094 A1
(43) Pub. Date: Feb. 29, 2024

(54) PIPING, SEMICONDUCTOR MANUFACTURING APPARATUS, AND METHOD FOR MANUFACTURING SEMICONDUCTOR DEVICE

(71) Applicant: Kioxia Corporation, Tokyo (JP)

(72) Inventor: Yuya MATSUBARA, Kobe Hyogo (JP)

(73) Assignee: Kioxia Corporation, Tokyo (JP)

(21) Appl. No.: 18/454,234

(22) Filed: Aug. 23, 2023

(30) Foreign Application Priority Data
Aug. 25, 2022 (JP) 2022-134410

(51) Int. Cl. C23C 16/44; C23C 16/455; H01J 37/32

(52) U.S. Cl. CPC C23C 16/4412; C23C 16/45591; H01J 37/32623; H01J 2237/022; H01J 2237/3321

(57) ABSTRACT

A piping includes a first pipe part having a first end connected to a processing chamber and a second end connected to another piping; a second pipe part connected to the first pipe between the first end and the second end, and configured to supply hydrogen gas or hydrogen radicals into the first pipe part; a valve provided between the second pipe part and the second end, and configured to open and close the first pipe part; and a metal film coated on an inner wall of the first pipe part.

### CROSS-REFERENCE TO RELATED APPLICATION

This application is based upon and claims the benefit of priority from Japanese Patent Application No. 2022-134410, filed Aug. 25, 2022, the entire contents of which are incorporated herein by reference.

### FIELD

Embodiments described herein relate generally to a piping, a semiconductor manufacturing apparatus, and a method for manufacturing a semiconductor device.

### BACKGROUND

In a semiconductor manufacturing apparatus such as a plasma chemical vapor deposition (CVD) apparatus, there is a problem that a process gas exhaust pipe is clogged.

### DESCRIPTION OF THE DRAWINGS

FIG. 1 is a schematic diagram illustrating a configuration example of a semiconductor manufacturing apparatus according to a first embodiment.

FIG. 2 is a schematic cross-sectional view illustrating an example of a configuration and function of a piping.

FIG. 3 is a schematic cross-sectional view illustrating an example of the configuration and function of the piping.

FIG. 4 is a schematic cross-sectional view illustrating an example of a configuration of a semiconductor manufacturing apparatus according to a second embodiment.

### DETAILED DESCRIPTION

Embodiments provide a piping, a semiconductor manufacturing apparatus, and a method for manufacturing a semiconductor device that can prevent clogging of a process gas exhaust pipe.

In general, according to one embodiment, there is provided a piping that includes a first pipe part having a first end connected to a processing chamber and a second end connected to another piping; a second pipe part connected to the first pipe between the first end and the second end, and configured to supply hydrogen gas or hydrogen radicals into the first pipe part; a valve provided between the second pipe part and the second end, and configured to open and close the first pipe part; and a metal film coated on an inner wall of the first pipe part.

Hereinafter, embodiments of the present disclosure will be described with reference to the drawings. This embodiment does not limit the present disclosure. The drawings are schematic or conceptual, and the ratio of respective parts and the like are not necessarily the same as those in reality. In the specification and the drawings, elements that are the same as those described above with respect to the previous drawings are denoted by the same reference numerals, and detailed description thereof will be omitted as appropriate.

### First Embodiment

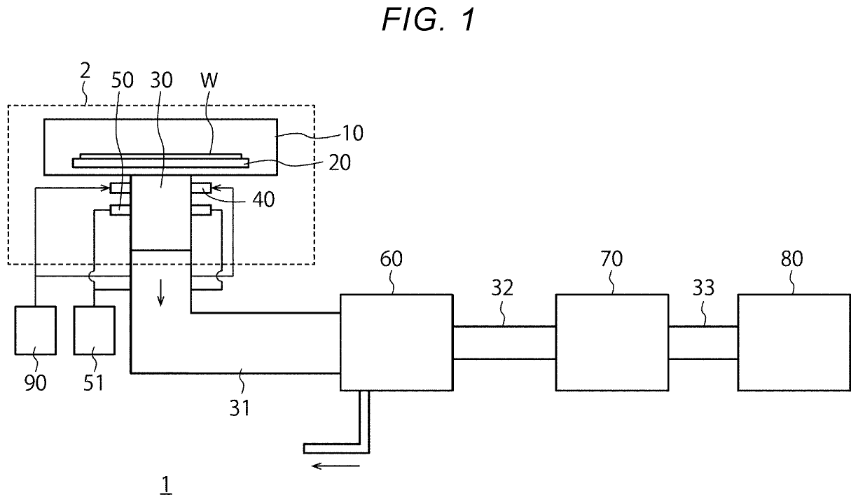

FIG. 1 is a schematic diagram illustrating a configuration example of a semiconductor manufacturing apparatus 1 according to a first embodiment. The semiconductor manufacturing apparatus 1 may be, for example, a film forming apparatus that turns process gas into plasma and ionizes plasma to process a semiconductor substrate, such as a plasma chemical vapor deposition (CVD) apparatus. The semiconductor manufacturing apparatus 1 may also be applied to a semiconductor manufacturing apparatus other than the plasma CVD apparatus.

The semiconductor manufacturing apparatus 1 includes a processing chamber 10, a stage 20, and a piping 30.

The processing chamber 10 accommodates a semiconductor substrate (hereinafter simply referred to as wafer) W and is used to form a material film on the wafer W by turning the process gas which is introduced into the processing chamber 10 into plasma. The stage 20 is provided in the processing chamber 10, and the wafer W can be placed on the stage 20. Although not illustrated, the processing chamber 10 is connected to a piping for introducing gases such as process gas and purge gas.

The piping 30 is connected to the processing chamber 10 and is provided for exhausting the process gas used for processing the wafer W in the processing chamber 10 from the processing chamber 10 to the outside. One end of the piping 30 is connected to the processing chamber 10 and the other end thereof is connected to another piping 31. The configuration and function of the piping 30 will be described later.

The piping 30 is provided with a hydrogen supply piping 40 and a valve 50. The hydrogen supply piping 40 is connected between one end and the other end of the piping 30. One end of the hydrogen supply piping 40 is connected to the piping 30 and the hydrogen supply piping 40 supplies hydrogen gas into the piping 30. The other end of the hydrogen supply piping 40 is connected to a hydrogen supply unit 90 and the hydrogen supply piping 40 introduces hydrogen gas from the hydrogen supply unit 90 into the piping 30. The hydrogen supply piping 40 is connected to the piping 30 between the chamber 10 and the valve 50. In the piping 30, the hydrogen gas from the hydrogen supply piping 40 is converted into hydrogen radicals and the process gas exhausted from the processing chamber 10 is hydrogenated.

The valve 50 is provided between the hydrogen supply piping 40 and the other end of the piping 30, that is, downstream from the hydrogen supply piping 40, and can open and close the inside of the piping 30. For example, when the valve 50 is open, the piping 30 is open and gas from the processing chamber 10 flows downstream from the valve 50. Accordingly, gas from the processing chamber 10 can be exhausted through the piping 30. When the valve 50 is closed, the piping 30 is clogged and gas from the processing chamber 10 does not flow downstream from the valve 50. Accordingly, the gas from the processing chamber 10 is not exhausted through the piping 30. The valve 50 is connected to a valve control unit 51 and opens and closes the inside of the piping 30 under the control of the valve control unit 51. The downstream indicates the direction in which gas flows, and the upstream indicates the direction opposite to the direction in which the gas flows.

The valve 50 can adjust the pressure inside the processing chamber 10 by the degree of opening and closing of the valve 50 (the degree of opening of the piping 30). For example, when the valve 50 is slightly open (when the degree of opening of the piping 30 is small), the pressure in the processing chamber 10 increases. On the other hand, when the valve 50 is wide open (when the degree of opening of the piping 30 is large), the pressure in the processing chamber 10 decreases.

The piping 30 is connected between the processing chamber 10 and a piping 31. The piping 31 is connected between the piping 30 and a process gas recovery device 60. A piping 32 is connected between the process gas recovery device 60 and a vacuum pump 70. A piping 33 is connected between the vacuum pump 70 and an abatement device 80.

The process gas exhausted from the processing chamber 10 is hydrogenated by hydrogen radicals in the piping 30, and then passed through the piping 31 and cooled in the process gas recovery device 60. The process gas recovery device 60 cools and liquefies the hydrogenated process gas using, for example, liquid nitrogen or the like. The liquefied process gas is recovered for reuse in wafer W processing.

The gas that passed through the process gas recovery device 60 is passed through the piping 32 and is sent to the abatement device 80 by the vacuum pump 70. The vacuum pump 70 communicates with the processing chamber 10 through the piping 30 to 32 and reduces the pressure in the processing chamber 10.

The gas that passed through the vacuum pump 70 is heated and detoxified in the abatement device 80 and discharged to the outside.

The hydrogen supply unit 90 stores hydrogen and supplies hydrogen gas into the piping 30 through the hydrogen supply piping 40.

The semiconductor manufacturing apparatus 1 includes the processing chamber 10 and the piping 30, and the piping 30 is detachable from the processing chamber 10 and may be replaced. Accordingly, the semiconductor manufacturing apparatus 1 includes at least the processing chamber 10, and the configurations provided downstream the piping 30 such as the piping 30 to 33, the process gas recovery device 60, the vacuum pump 70, the abatement device 80, the hydrogen supply unit 90, and the like may be externally attached to the semiconductor manufacturing apparatus 1 as a separate configuration.

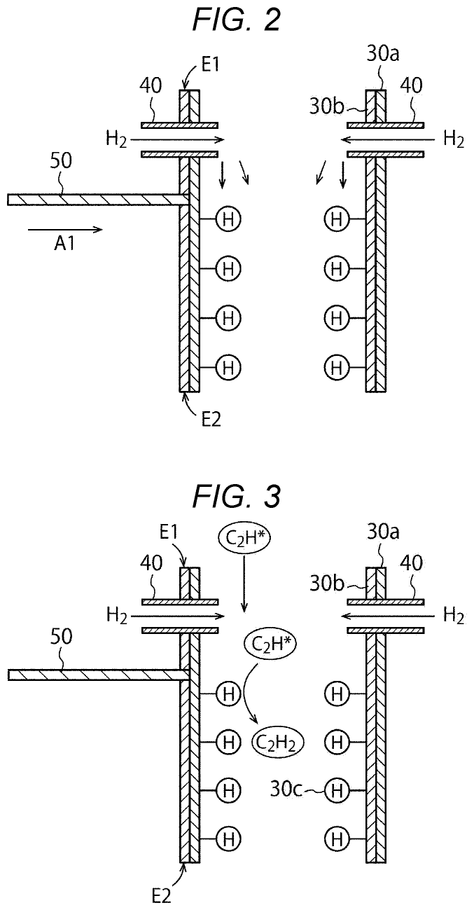

FIGS. 2 and 3 are schematic cross-sectional views illustrating an example of the configuration and function of the piping 30. FIG. 2 illustrates a state of hydrogen gas being supplied into the piping 30. FIG. 3 illustrates a state of the process gas being hydrogenated.

The piping 30 includes a pipe part 30a, the hydrogen supply piping 40, the valve 50, and a metal film 30b. An end E1 of the pipe part 30a is connected to the processing chamber 10 and an end E2 thereof is connected to another piping 31. A corrosion-resistant material such as stainless steel (SUS) containing Fe, Ni, or the like is used for the pipe part 30a.

The hydrogen supply piping 40 is connected in the middle of the piping 30 between the end E1 and the end E2, and can supply hydrogen gas into the piping 30. Similar to the pipe part 30a, a corrosion-resistant material such as stainless steel (SUS) containing Fe, Ni, or the like is used for the hydrogen supply piping 40.

The valve 50 is provided between the hydrogen supply piping 40 and the end E2 and is configured to open and close the piping 30. The valve 50 closes the piping 30 by moving in the direction of an arrow μl and opens the piping 30 by moving in the opposite direction of the arrow μl. In FIG. 2, a state in which the valve 50 opens the piping 30 is illustrated. Similar to the pipe part 30a, a corrosion-resistant material such as stainless steel (SUS) containing Fe, Ni, or the like is also used for the valve 50.

The metal film 30b covers an inner wall of the pipe part 30a. The metal film 30b is made of, for example, a material for hydrogenating hydrocarbon radicals and converting the hydrogenated hydrocarbon radicals into hydrogen carbonate gas. For the metal film 30b, for example, a single layer of any of ruthenium (Rh), palladium (Pd), platinum (Pt), nickel (Ni), and iron (Fe), or a stacked film of two or more kinds of Rh, Pd, Pt, Ni, and Fe is used. The metal film 30b functions as a metal catalyst for hydrogenating the process gas.

For example, when hydrocarbon gas CₘHₙ is used as the process gas, radical gas CₘHₙ₋ₚ (hereinafter also referred to as CₘHₙ*) in which the hydrocarbon gas CₘHₙ is ionized and radicalized is generated. m and n are positive integers, and p is a positive integer less than or equal to n. The radical gas CₘHₙ* may also be hereinafter referred to as process gas.

The radical gas CₘHₙ* is used for processing the wafer W, but some of the radical gas is exhausted without being used. In this case, the radical gas CₘHₙ* flows into the piping 30.

If the metal film 30b is not provided on the inner wall of the pipe part 30a, the radical gas CₘHₙ* is adsorbed on the inner wall of the pipe part 30a and stabilized. If this is repeated, there is a concern that deposits (hydrocarbon) derived from the radical gas CₘHₙ* may clog the pipe part 30a.

In particular, in the vicinity of the valve 50, a flow of the process gas changes, and a flow velocity of the process gas tends to change. For example, if the valve 50 is slightly open, the flow velocity of the process gas passing through the valve 50 rapidly increases at a position located immediately near the downstream side of the valve 50. In this case, at the position located immediately near the downstream side of the valve 50, deposits derived from the process gas tend to adhere to the inner wall of the pipe part 30a and tend to clog the pipe part 30a.

In contrast, according to this embodiment, the metal film 30b that functions as a catalyst for hydrogenating the radical gas CₘHₙ* is provided on the inner wall of the pipe part 30a. The metal film 30b radicalizes the hydrogen gas from the hydrogen supply piping 40 and generates hydrogen radicals. The radical gas CₘHₙ* reacts with hydrogen radicals and is hydrogenated into hydrocarbon gas CₘHₙ. Hydrocarbon gas is relatively stable and does not accumulate in the piping 30 and flows downstream. For example, as illustrated in FIG. 3, when the radical gas C₂H* flows into the piping 30, the metal film 30b functions as a catalyst to hydrogenate the radical gas C₂H* with hydrogen radicals. With this configuration, the radical gas C₂H* becomes hydrocarbon gas C₂H₂ and flows downstream in a gaseous state without being deposited in the piping 30.

A catalyst that hydrogenates hydrocarbon radicals is used for the metal film 30b. For the metal film 30b, for example, a single layer of any of ruthenium (Rh), palladium (Pd), platinum (Pt), nickel (Ni), and iron (Fe), or a stacked film of two or more kinds of Rh, Pd, Pt, Ni and Fe is used.

Although the hydrocarbon gas CₘHₙ is mentioned as an example of the process gas, any material that may be hydrogenated and become gas may be used as the process gas. For example, the main component of the process gas may be any of boron (B), carbon (C), silicon (Si), phosphorus (P), sulfur (S), germanium (Ge), and arsenic (As).

For example, when the process gas is gas, which contains boron (B), (B₂H₆, BF₃, or BCl₃), or the like, boron nitride (BN), boron carbide (BC), B-doped SiO₂ containing boron, and the like tend to deposit as by-products. However, according to this embodiment, the metal film 30b hydrogenates the process gas and the by-products, so that the process gas and by-products are produced as process gas B₂H₆ or the like and discharged.

When the process gas is gas, which contains carbon (C), (CH₄, C₂H₆, C₃H₈, C₄H₁₀, C₂H₄, C₃H₆, C₄H₈, C₂H₂, C₃H₄, C₄H₆, CF₄, C₄F₆, or C₄F₈), carbon, CₓF_{y} (where x and y are positive integers), and the like tend to deposit as by-products. However, according to this embodiment, the metal film 30b hydrogenates the process gas and the by-products, so that the process gas and by-product are produced as process gases CH₄, C₂H₆, C₃H₈, C₄H₁₀, C₂H₄, C₃H₆, C₄H₈, C₂H₂, C₃H₄, C₄H₆, and the like and discharged.

When the process gas is gas, which contains silicon (Si), (SiH₄, Si₂H₆, or SiF₄), silicon, silicon oxide, silicon nitride, and the like tend to deposit as by-products. However, according to this embodiment, the metal film 30b hydrogenates the process gas and the by-products, so that the process gas and by-products are produced as process gases SiH₄, Si₂H₆, and the like and discharged.

When the process gas is gas PH₃ containing phosphorus (P), P-doped Si, P-doped SiO₂, and the like tend to deposit as by-products. However, according to this embodiment, the metal film 30b hydrogenates the process gas and the by-products, so that the process gas and by-products are produced as process gas PH 3 or the like and is discharged.

When the process gas is gas AsH₃ containing arsenic (As), As-doped Si, As-doped SiO₂, and the like tend to deposit as by-products. However, according to this embodiment, the metal film 30b hydrogenates the process gas and the by-products, so that the process gas and by-products are produced as process gas AsH₃ or the like and discharged.

Thus, even if the main component of the process gas is any one of boron (B), carbon (C), silicon (Si), phosphorus (P), sulfur (S), germanium (Ge), or arsenic (As), the metal film 30b can hydrogenate the process gas and discharge the process gas as gas.

With this configuration, in this embodiment, the process gas is not deposited on the inner wall of the piping 30, passes through the piping 30 and the valve 50, and flows downstream in a gaseous state. For example, deposits derived from the process gas is not adhered even in the vicinity of the valve 50, and clogging of the valve 50 is hardly to occur.

The flow rate of the hydrogen gas supplied from the hydrogen supply piping 40 is preferably higher than the flow rate of the process gas supplied to the chamber 10. With this configuration, the exhausted process gas may be sufficiently hydrogenated.

In the process gas recovery device 60, liquid nitrogen cools and liquefies the hydrogenated process gas. For example, process gases CH₄, C₃H₆, C₂H₂, B₂H₆, SiH₄, PH₃, AsH₄, and the like have higher boiling points than nitrogen and thus, may be liquefied and recovered in the process gas recovery device 60. The recovered process gas may be reused for wafer W processing.

The gas that passed through the process gas recovery device 60 and the vacuum pump 70 is combusted and detoxified in the abatement device 80 and discharged to the outside.

In this embodiment, the inner wall of the piping 30 is covered with the metal film 30b. However, the metal film 30b may cover the inner walls of other piping 31 to 33. With this configuration, clogging of the piping 31 to 33 is also prevented. Further, by providing the metal film 30b on the inner wall of the piping 31, more process gas is hydrogenated. Accordingly, the process gas recovery device 60 can recover more process gas. Method for manufacturing semiconductor device

In a method for manufacturing a semiconductor device using the semiconductor manufacturing apparatus 1 according to this embodiment, first, the wafer W is loaded into the processing chamber 10 and placed on the stage 20.

Next, the process gas is introduced into the processing chamber 10 to process the wafer W. With this configuration, a desired material film is formed on a front surface of the wafer W, for example.

After the wafer W is processed, the used process gas is exhausted from the processing chamber 10 to the piping 30. In this case, hydrogen adsorbed on the metal film 30b becomes hydrogen radicals and hydrogenates the process gas. In this case, the flow rate of the hydrogen gas supplied from the hydrogen supply piping 40 is preferably higher than the flow rate of the process gas supplied to the chamber 10. With this configuration, the exhausted process gas may be sufficiently hydrogenated.

Thereafter, the hydrogenated process gas is recovered by the process gas recovery device 60, or detoxified in the abatement device 80 and discharged to the outside.

With this configuration, the process gas is not deposited on the inner wall of the piping 30, is hydrogenated, passes through the piping 30 and the valve 50, and flows downstream in a gaseous state. As a result, deposits derived from the process gas are not adhered to the piping 30, and clogging of the piping 30 may be prevented.

### Second Embodiment

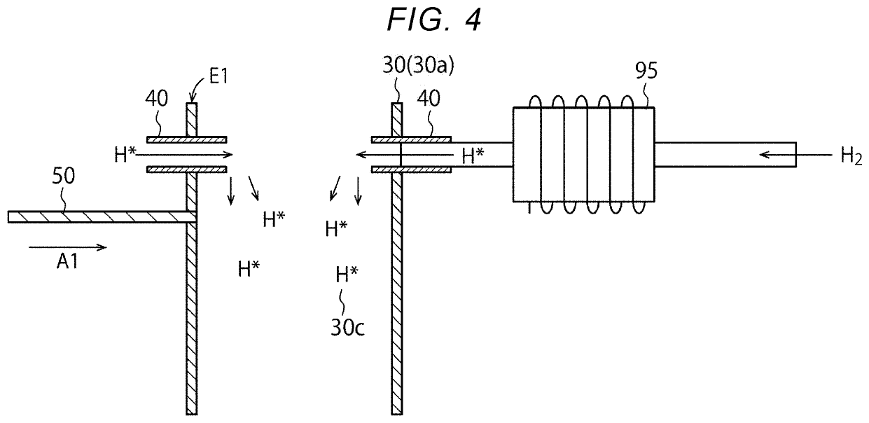

FIG. 4 is a schematic cross-sectional view illustrating an example of a configuration of a semiconductor manufacturing apparatus according to a second embodiment. In the second embodiment, the metal film 30b is not provided, and a hydrogen radical generator 95 is connected to a piping 40 instead. The hydrogen radical generator 95 is a device that receives hydrogen gas H₂ from the hydrogen supply unit 90 and ionizes the hydrogen gas H₂ by plasma to generate hydrogen radicals 30c (for example, H*). The hydrogen radicals 30c generated by the hydrogen radical generator 95 are supplied from the piping 40 into the piping 30. Since the hydrogen radical generator 95 supplies hydrogen radicals into the piping 30, the metal film 30b functioning as a catalyst is not required.

Other configurations of the second embodiment may be the same as corresponding configurations of the first embodiment. As in the second embodiment, the hydrogen radicals 30c may be generated outside the piping 30 and supplied into the piping 30. As in the second embodiment, the hydrogen radicals 30c may be generated outside the piping 30 and supplied into the piping 30. Even in this way, the process gas exhausted to the piping 30 is hydrogenated, passes through the piping 30, and flows downstream in a gaseous state. As a result, deposits derived from the process gas are not adhered to the piping 30, and clogging of the piping 30 may be prevented.

The method for manufacturing the semiconductor device according to the second embodiment differs from the first embodiment in that the hydrogen radical generator 95 generates hydrogen radicals 30c outside the piping 30 and supplies the hydrogen radicals 30c into the piping 30. However, other steps of the second embodiment may be the same as those of the first embodiment. Accordingly, in the second embodiment, the same effect as in the first embodiment can be obtained.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A piping that exhausts a process gas from a processing chamber of a semiconductor manufacturing apparatus, the piping comprising:
a first pipe part having a first end connected to a processing chamber and a second end connected to another piping;
a second pipe part connected to the first pipe between the first end and the second end, and configured to supply hydrogen gas or hydrogen radicals into the first pipe part;
a valve provided between the second pipe part and the second end, and configured to open and close the first pipe part; and
a metal film coated on an inner wall of the first pipe part.

2. The piping according to claim 1, wherein
the metal film includes a single layer of any one of ruthenium (Rh), palladium (Pd), platinum (Pt), nickel (Ni), and iron (Fe), or a stacked film of two or more kinds of Rh, Pd, Pt, Ni, and Fe.

3. The piping according to claim 1, wherein
the metal film is made of a material that hydrogenates radicals.

4. A semiconductor manufacturing apparatus, comprising:
a processing chamber for processing a substrate with a process gas;
a first pipe part having a first end connected to the processing chamber and a second end connected to a piping, the first pipe part configured to exhaust the process gas from the processing chamber;
a second pipe part connected to the first pipe part between the first end and the second end, and configured to supply hydrogen gas into the first pipe part;
a valve provided between the second pipe part and the second end, and configured to open and close the first pipe part; and
a metal film coated on an inner wall of the first pipe part.

5. A semiconductor manufacturing apparatus, comprising:
a processing chamber for processing a substrate with a process gas;
a first pipe part having a first end connected to the processing chamber and a second end connected to a piping, the first pipe part configured to exhaust the process gas from the processing chamber;
a second pipe part connected to the first pipe part between the first end and the second end, and configured to supply hydrogen gas into the first pipe part;
a valve provided between the second pipe part and the second end, and configured to open and close the first pipe part; and
a radical generator connected to the second pipe part and configured to generate hydrogen radicals from hydrogen gas.

6. The apparatus according to claim 4, wherein
the metal film includes a single layer of any one of ruthenium (Rh), palladium (Pd), platinum (Pt), nickel (Ni), and iron (Fe), or a stacked film of two or more kinds of Rh, Pd, Pt, Ni, and Fe.

7. The apparatus according to claim 4, wherein
the metal film is made of a material that hydrogenates radicals.

8. The apparatus according to claim 4, wherein
a flow rate of the hydrogen gas supplied from the second pipe part is higher than a flow rate of the process gas.

9. A method for manufacturing a semiconductor device using a semiconductor manufacturing apparatus that processes a substrate with a process gas, the method comprising:
introducing the process gas into a processing chamber to process a substrate; and
in a first pipe part that exhausts the process gas from the processing chamber, supplying hydrogen gas or hydrogen radicals from a second pipe part connected to the first pipe part into the first pipe part to hydrogenate the process gas.
